(19) United States
(12) Patent Application Publication
(10) Pub. No.: US 2013/0264480 A1
(43) Pub. Date: Oct. 10, 2013

(54) PATTERN MEASUREMENT METHOD AND PATTERN MEASUREMENT APPARATUS

(71) Applicants: ADVANTEST CORPORATION, Tokyo (JP); TOPPAN PRINTING CO., LTD., Tokyo (JP)

(72) Inventors: Tsutomu Murakawa, Tokyo (JP); Isao Yonekura, Tokyo (JP)

(73) Assignees: TOPPAN PRINTING CO., LTD., Tokyo (JP); ADVANTEST CORPORATION, Tokyo (JP)

(21) Appl. No.: 13/858,676

(22) Filed: Apr. 8, 2013

(30) Foreign Application Priority Data
Apr. 9, 2012 (JP) 2012-088418

(51) Int. Cl. H01J 37/22

(52) U.S. Cl. CPC H01J 37/222
USPC 250/307; 250/310

(57) ABSTRACT

A pattern measurement method and a pattern measurement apparatus which use a scanning electron microscope are provided. SEM images of a measurement target pattern are respectively acquired at least two predetermined acceleration voltages. White band widths of the measurement target pattern are detected from the acquired SEM images. Then, an amount of change in the white band width between the predetermined acceleration voltages is calculated. A side wall angle of the measurement target pattern is calculated on the basis of a relation between an amount of change in a white band width and a side wall angle experimentally obtained in advance by using a sample with a known side wall angle.

### CROSS-REFERENCE TO RELATED ART

This application is based upon and claims benefit of priority of the prior Japanese Patent Application No. 2012-088418, filed on Apr. 9, 2012, the entire contents of which are incorporated herein by reference.

### TECHNICAL FIELD

The embodiments discussed herein are related to a pattern measurement method and a pattern measurement apparatus, which use an electron beam.

### BACKGROUND ART

Microfabrication techniques have been advanced in recent years. The microfabrication techniques are applied to semiconductor devices, optical elements, wiring circuits, recording media such as hard disks and DVDs, medical testing chips used for DNA analyses, display panels, microchannels, microreactors, MEMS devices, imprint molds, photomasks, and so forth.

In the microfabrication techniques, it is important to evaluate not only two-dimensional shapes such as pattern dimensions but also three-dimensional shapes such as side wall angles at edge portions of patterns.

Accordingly, a method of measuring a side wall angle by focusing on a width of a white band representing a high-luminance portion appearing at a side wall portion of a pattern on a scanning electron microscopic image (SEM image) has been proposed as one of methods of measuring a side wall angle.

However, in a reverse tapered pattern, a side wall is hidden beneath the pattern and a relation between a white band width and a side wall angle is unclear. As a consequence, the aforementioned method cannot measure such a side wall angle.
[Patent Document 1] Japanese Laid-open Patent Publication No. 10-170530
[Patent Document 2] Japanese Laid-open Patent Publication No. 2008-71312

### SUMMARY OF THE INVENTION

In view of the above, it is an object of the present invention to provide a pattern measurement method and a pattern measurement apparatus, which are capable of measuring a side wall angle of a reverse tapered pattern.

According to an aspect of the invention provides, a pattern measurement method including the steps of: acquiring scanning electron microscopic images of a measurement target pattern respectively at least two predetermined acceleration voltages; detecting white band widths of the measurement target pattern from the scanning electron microscopic images; finding an amount of change in the white band width by obtaining a difference between the detected white band widths; and finding a side wall angle of the measurement target pattern based on the amount of change in the white band width.

Another aspect of the invention provides a pattern measurement apparatus including: an electron scanning unit configured to scan a measurement target pattern with an electron beam at least two predetermined acceleration voltages; a signal processing unit configured to acquire a scanning electron microscopic image based on secondary electrons generated by the scanning of the electron beam at the predetermined acceleration voltages respectively; and a measurement data processing unit configured to find a side wall angle of the measurement target pattern based on the scanning electron microscopic images acquired by the signal processing unit, wherein the measurement data processing unit detects white band widths of the measurement target pattern from the scanning electron microscopic images, finds an amount of change in the white band width by obtaining a difference between the detected white band width, and finds a side wall angle of the measurement target pattern based on the amount of change in the white band width.

According to the pattern measurement method of the above-described aspect, the amount of change in the white band width is detected from the SEM images captured at different acceleration voltages. The amount of change in the white band width varies depending on the side wall angle in the case of a reverse tapered pattern. As a consequence, the side wall angle of the reverse tapered pattern can be measured by the measurement method of the above-described aspect.

### BRIEF DESCRIPTION OF THE DRAWINGS

FIG. 1 is a block diagram of a pattern measurement apparatus according to a first embodiment.

FIGS. 2A and 2B are cross-sectional views for explaining how an amount of change in a white band width varies depending on a side wall angle.

FIG. 3 is a flowchart showing how to find a relation between the side wall angle and the amount of change in the white band width in a pattern measurement method according to the first embodiment.

FIG. 4 is a flowchart showing a method of measuring the side wall angle in the pattern measurement method according to the first embodiment.

FIG. 5 is a flowchart showing a method of measuring a side wall angle in a pattern measurement method according to a second embodiment.

FIG. 6 is a graph showing a result of measurement of the white band widths regarding reference patterns of an experimental example, in which the horizontal axis indicates an acceleration voltage and the vertical axis indicates the white band width.

### DESCRIPTION OF EMBODIMENTS

Embodiments of the present invention will be described below with reference to the accompanying drawings.

### First Embodiment

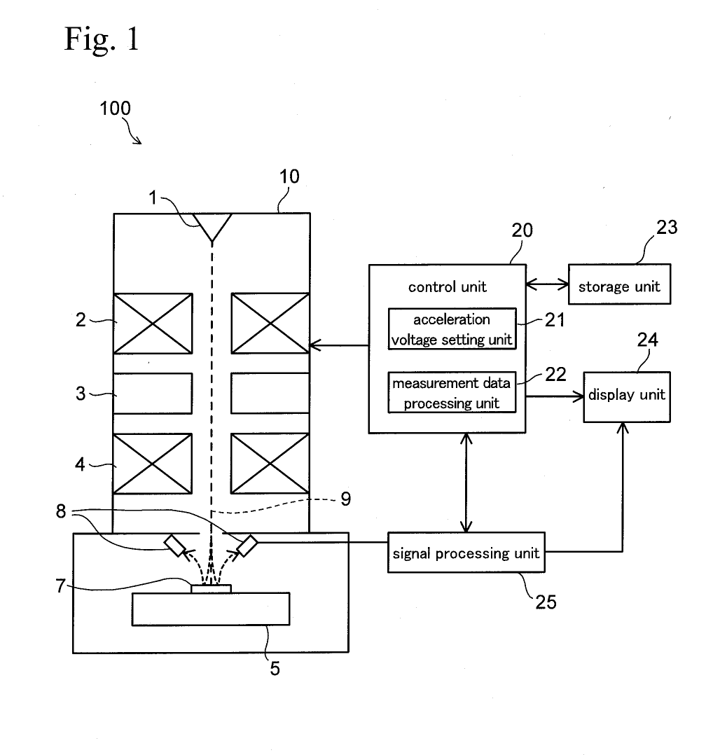

FIG. 1 is a block diagram of a pattern measurement apparatus according to a first embodiment.

This pattern measurement apparatus 100 includes an electron scanning unit 10, a control unit 20, a storage unit 23, an image display unit 24, and a signal processing unit 25.

Among them, the electron scanning unit 10 includes an electron gun 1. The electron gun 1 emits electrons at given acceleration voltages. The electrons emitted from the electron gun 1 are converged with a condenser lens 2 and are thereby converted into an electron beam 9. The electron beam 9 is deflected with a deflection coil 3, then focused with an objective lens 4, and irradiated onto a surface of a sample 7. Thereafter, the electron beam 9 is caused to scan within an observation region on the surface of the sample 7 by using the deflection coil 3.

Secondary electrons are emitted from the surface of the sample 7 as a consequence of irradiation with the electron beam 9. The emitted secondary electrons are detected with one or a plurality of electron detectors 8 provided above a sample stage 5.

The signal processing unit 25 converts amounts of the detected secondary electrons into digital amounts by using an AD converter (not shown), and associates the amounts of the secondary electrons with positions of irradiation with the primary electron beam 9, thereby generating a secondary electron image (a SEM image) of the surface of the sample 7. The SEM image generated by the signal processing unit 25 is displayed on the image display unit 24 and is sent to the control unit 20.

The control unit 20 includes an acceleration voltage setting unit 21 and a measurement data processing unit 22. Here, the acceleration voltage setting unit 21 controls the acceleration voltage of the electron beam 9 emitted from the electron gun 1.

The control unit 20 acquires two SEM images captured at two acceleration voltages predetermined by using the acceleration voltage setting unit 21. In the SEM images thus acquired, a large amount of the secondary electrons are emitted from a side wall portion of a pattern. Accordingly, a side wall looks bright in a strip shape. In this specification, the portion looking bright will be referred to as a white band.

The measurement data processing unit 22 detects widths of the white band in a measurement target pattern respectively from the two SEM images, and finds an amount of change in the white band width by obtaining a difference between the detected white band widths. Then, the measurement data processing unit 22 calculates a side wall angle θ of the measurement target pattern based on a relation between the side wall angle θ and the amount of change in the white band width measured in advance by using reference patterns.

Now, relations among the side wall angle of the pattern, the acceleration voltage of the electron beam, and the white band width will be described below.

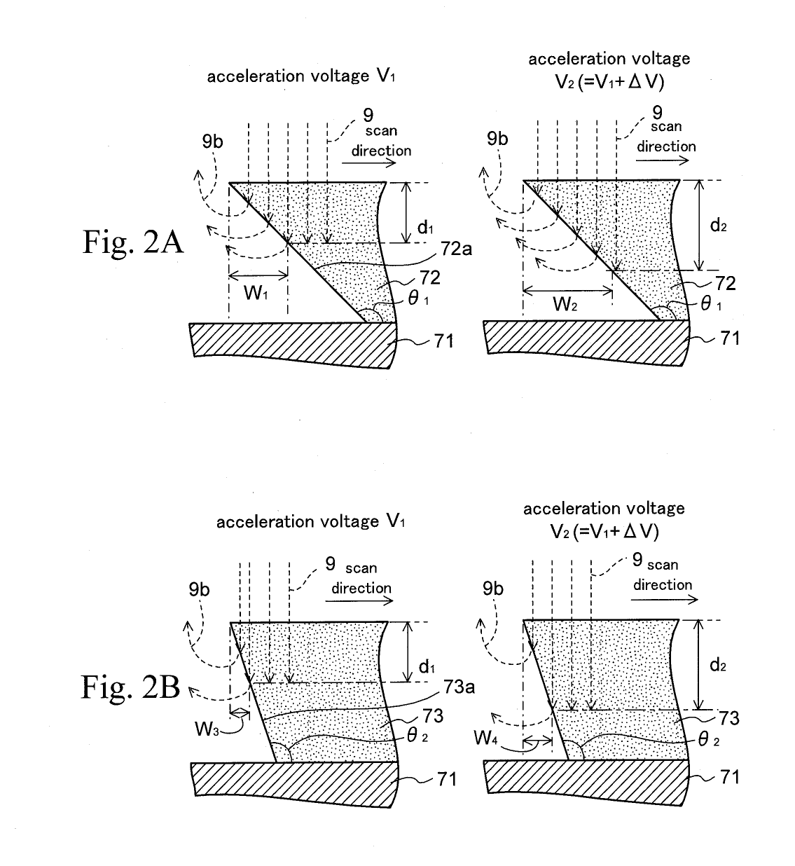

FIGS. 2A and 2B are cross-sectional views for explaining how the white band widths in reverse tapered patterns change depending on the acceleration voltages.

A pattern 72 shown in FIG. 2A is a reverse tapered pattern having a side wall angle θ₁ greater than 90°.

When the electron beam 9 at an acceleration voltage V₁ scans the pattern 72, the electron beam 9 reaches a range at a depth d₁ of the pattern 72. Then, an amount of emission of secondary electrons 9b increases in a portion of a side wall 72a thinner than the depth d₁, whereby a white band having a width W₁ appears on a SEM image.

Here, when the acceleration voltage V₁ of the electron beam 9 is further increased by ΔV to an acceleration voltage V₂, the electron beam 9 reaches a range at a depth d₂ which is deeper than d₁. Thus, the amount of emission of the secondary electrons 9b increases in a portion of the side wall 72a thinner than the depth d₂, whereby the white band width on the SEM image increases to W₂.

As a consequence, in the pattern 72, the white band width changes by ΔW=W₂−W₁ relative to a certain amount of change ΔV in the acceleration voltage.

In the meantime, a pattern 73 in FIG. 2B is a reverse tapered pattern having a side wall angle θ₂ greater than 90°. Here, the inclination of the side wall 73a is closer to the vertical than that of the side wall 72a of the pattern 72.

When the electron beam 9 scans the pattern 73 with the acceleration voltage V₁ and the acceleration voltage V₂, the electron beam 9 with the acceleration voltage V₁ and the electron beam 9 with the acceleration voltage V₂ reach the ranges at the depth d₁ and the depth d₂, respectively.

However, due to the steep inclination of the side wall 73a, white band widths W₃ and W₄ at the acceleration voltages V₁ and V₂ become narrower than the corresponding white band widths W₁ and W₂ of the pattern 72. Hence, the amount of change ΔW (=W₄−W₃) in the white band width of the pattern 73 becomes smaller than the amount of change ΔW (=W₂−W₁) in the white band width of the pattern 72.

As described above, in the reverse tapered pattern, the amount of change ΔW in the white band width obtained from the two SEM images captured at the two acceleration voltages V₁ and V₂ shows a variation corresponding to the side wall angle θ.

Accordingly, in the embodiment, the two SEM images captured at the two predetermined acceleration voltages V₁ and V₂ are acquired from each of a plurality of reference patterns having known side wall angles. Then, a relation between the side wall angle θ and the amount of change ΔW in the white band width is obtained in advance based on the SEM images.

Further, a side wall angle of a measurement target pattern is found by use of the relation between the side wall angle θ and the amount of change ΔW in the white band width.

Now, specific procedures of the embodiment will be described below.

<How to Find Relation between Side Wall Angle and Amount of Change in White Band Width>

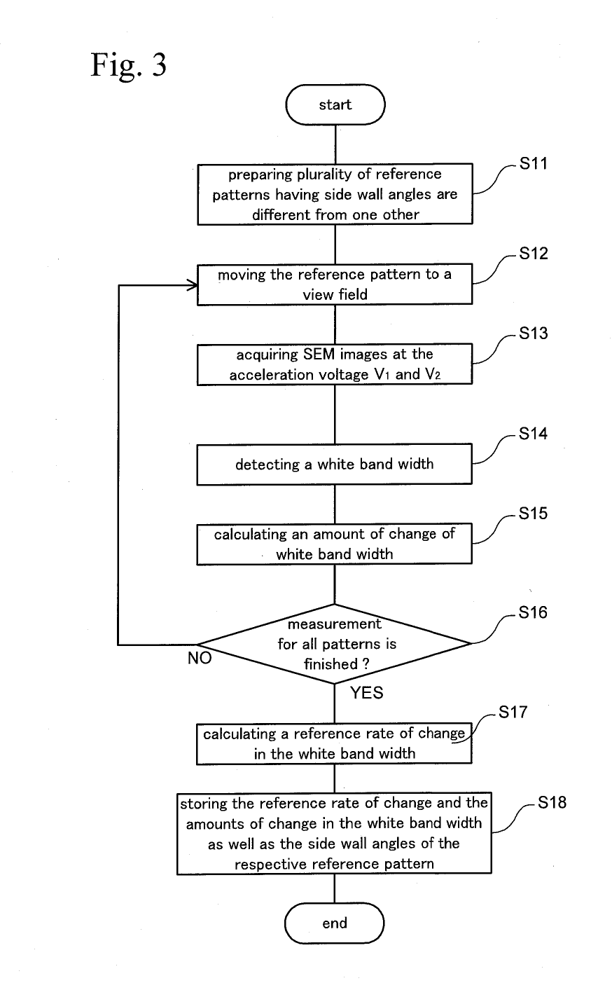

FIG. 3 is a flowchart showing how to find the relation between the side wall angle and the amount of change in the white band width in the pattern measurement method according to the embodiment.

First, a plurality of reverse tapered reference patterns having side wall angles which are known and different from one other are prepared in step S11 of FIG. 3. The side wall angles of the reference patterns may be obtained by observation in accordance with AFM (atomic force microscopy), for example.

The depth of the electron beam reaching the inside of a pattern varies depending on the material constituting the pattern. Accordingly, the amount of change in the white band width also varies depending on the material. As a consequence, the reference patterns are preferably made of the same material as the measurement target pattern.

Next, in step S12, the control unit 20 of FIG. 1 drives the stage 5 and moves a reference pattern to be measured first into a view field of the electron scanning unit 10.

Then, in step S13, the pattern measurement apparatus 100 acquires the SEM image at the acceleration voltage V₁ and the SEM image at the acceleration voltage V₂ under control of the control unit 20.

Next, in step S14, the measurement data processing unit 22 of the control unit 20 finds the white band widths of the reference pattern respectively from the SEM image at the acceleration voltage V₁ and the SEM image at the acceleration voltage V₂.

Subsequently, in step S15, the measurement data processing unit 22 finds the amount of change ΔW in the white band width by obtaining the difference between the white band width at the acceleration voltage V₁ and the white band width at the acceleration voltage V₂.

Thereafter, in step S16, the control unit 20 judges whether or not the measurement of all the reference patterns is completed.

The processing goes to step S12 if the control unit 20 judges in step S16 that the measurement of all the reference patterns is not completed yet (NO).

Then, in step S12, another reference pattern having a different inclination angle is moved into the view field of the electron scanning unit 10 by driving the stage 5 of the pattern measurement apparatus 100.

Thereafter, the processing of steps S13 to S15 is repeated.

On the other hand, the processing goes to step S17 if the control unit 20 judges in step S16 that the measurement of all the reference patterns is completed (YES).

In step S17, the measurement data processing unit 22 finds an amount of change in the white band width for each 1° change in the side wall angle. The amount of change in the white band width for each 1° change in the side wall angle will be hereinafter referred to as a reference rate of change. The reference rate of change possesses [length/change] dimensions.

In the simplest example, the reference rate of change is obtained from two reference patterns and in accordance with the following formula:

α=|ΔW_{A}−ΔW_{B}|/|θ_{A}−θ_{B}| (1)

where: α is the reference rate of change; ΔW_{A} is the amount of change in the white band width of one reference pattern A; ΔW_{B} is the amount of change in the white band width of the other reference pattern B; θ_{A} is the side wall angle of the one reference pattern A; and θ_{B} is the side wall angle of the other reference pattern B.

Then, in step S18, the control unit 20 stores the reference rate of change and the amounts of change in the white band width as well as the side wall angles of the respective reference patterns in the storage unit 23, and hence completes the processing for measuring the reference patterns.

The SEM images for finding the reference rate of change α may also be acquired by using a SEM simulator. Here, the SEM simulator is software which predicts a SEM image of a pattern by calculating behaviors of secondary electrons emitted when the pattern is irradiated with an electron beam emitted from an electron gun of a scanning electron microscope while using a Monte Carlo method.

The SEM images under desired conditions are acquired with the SEM simulator by appropriately setting the acceleration voltages of the electron beam, the material of the pattern, and the shape of the pattern. The reference rate of change α is found from the SEM images.

### <Method of Measuring Side Wall Angle>

Next, a method of measuring a side wall angle of a measurement target pattern will be described.

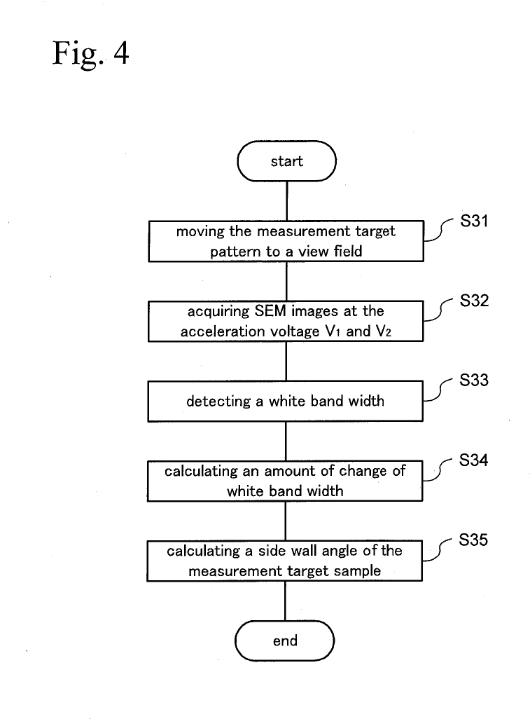

FIG. 4 is a flowchart showing a method of measuring the side wall angle in the pattern measurement method according to the embodiment.

First, in step S31 of FIG. 4, the control unit 20 of FIG. 1 drives the stage 5 and moves the measurement target pattern into the view field of the electron scanning unit 10.

Next, in step S32, the pattern measurement apparatus 100 acquires the SEM image at the acceleration voltage V₁ and the SEM image at the acceleration voltage V₂ under control of the control unit 20.

Then, in step S33, the measurement data processing unit 22 of the control unit 20 finds the white band widths of the measurement target pattern respectively from the SEM image at the acceleration voltage V₁ and the SEM image at the acceleration voltage V₂.

Next, in step S34, the measurement data processing unit 22 calculates the amount of change ΔW₁ in the white band width of the measurement target pattern by obtaining the difference between the white band width at the acceleration voltage V₁ and the white band width at the acceleration voltage V₂.

Subsequently, in step S35, the control unit 20 calculates the side wall angle θ₁ of the measurement target pattern.

Here, the measurement data processing unit 22 first reads the reference rate of change α, the side wall angle θ_{A} of the reference pattern A, and the amount of change ΔW_{A} in the white band width of the reference pattern A out of the storage unit 23. Then, the side wall angle θ₁ of the measurement target pattern is calculated in accordance with the following formula and on the basis of the reference rate of change α, the side wall angle θ_{A}, the amount of change ΔW_{A} in the white band width, and the amount of change ΔW₁ in the white band width of the measurement target pattern:

θ₁=θ_{A}+(ΔW₁−ΔW_{A})/α. (2)

Here, the side wall angle θ₁ of the measurement target pattern may be found by using the side wall angle θ_{B} and the amount of change ΔW_{B} in the white band width of the reference pattern B instead of the side wall angle θ_{A} and the amount of change ΔW_{A} of the pattern A. In this case, the side wall angle θ₁ of the measurement target pattern may be calculated in accordance with the following formula:

θ₁=θ_{B}+(ΔW₁−ΔW_{B})/α. (3)

Thus, the side wall angle θ₁ of the measurement target pattern is found.

Then, the measurement processing of the side wall angle of the measurement target pattern is terminated.

As described above, according to the embodiment, the side wall angle of the reverse tapered pattern is found by using the relation between the side wall angle and the amount of change in the white band width.

Thus, the side wall angle of the reverse tapered pattern can be measured by non-destructive inspection using the SEM images. In addition, according to the measurement method of the embodiment, it is possible to measure the side wall angle more quickly than in the case of using the AFM, and it is also easy to find the side wall angles at numerous measurement points using the SEM images.

### Second Embodiment

Researches conducted by the inventors of the present application have found out that a forward tapered pattern having a side wall angle equal to or below 90° shows no variation in the amount of change ΔW in the white band width when the side wall angle θ changes.

Accordingly, the method described with reference to FIG. 3 and FIG. 4 cannot measure an accurate side wall angle in the case of a forward tapered pattern.

It is therefore preferred to check whether the measurement target pattern is formed in a forward taper or a reverse taper.

A pattern measurement method according to a second embodiment is designed to judge whether or not the measurement target pattern is reverse tapered prior to the calculation of the side wall angle.

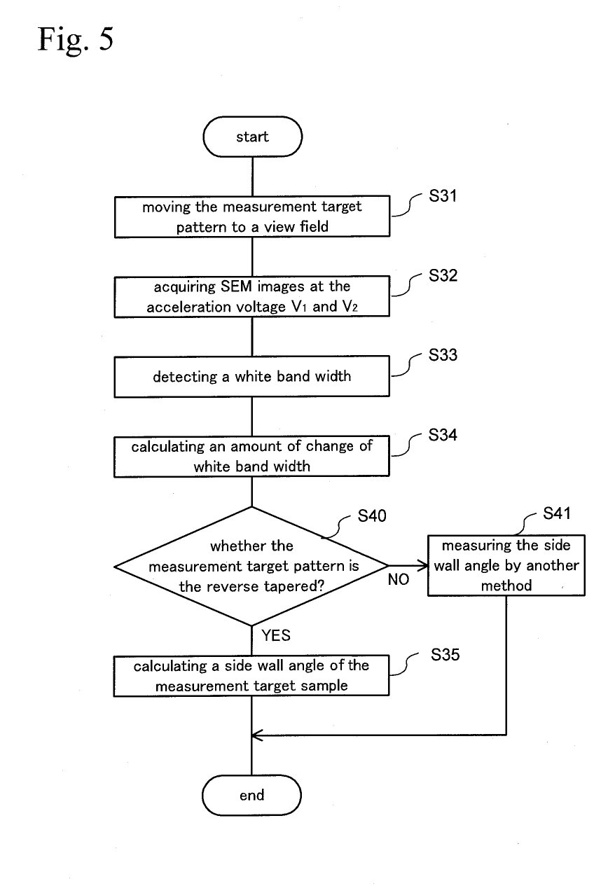

FIG. 5 is a flowchart showing a method of measuring a side wall angle in the pattern measurement method according to the embodiment.

In FIG. 5, the processing from step S31 to step S34 are similar to the measurement method described with reference to FIG. 4.

In the embodiment, a judgment is made in step S40 subsequent to step S34 as to whether or not the measurement target pattern is the reverse tapered pattern.

The judgment as to whether or not the measurement target pattern is reverse tapered can be made, for example, by checking whether or not the amount of change ΔW in the white band width in the case of changing the acceleration voltage by ΔV exceeds a predetermined threshold T. The threshold T is an amount of change in the white band width when the side wall angle is set at 90°, which is obtained by using the reference rate of change α, as well as the side wall angle θ_{B} and the amount of change ΔW_{B} in the white band width of the reference pattern B, and in accordance with the following formula:

T=ΔW_{B}−(θ_{B}−90)×α. (4)

The measurement target pattern is judged to be reverse tapered (YES) if the amount of change ΔW₁ in the white band width of the measurement target pattern is greater than the threshold T. In this case, the processing goes to step S35.

In step S35, the side wall angle of the measurement target pattern is calculated by a method similar to that described in step S35 of FIG. 4.

On the other hand, in step S40 of FIG. 5, the measurement target pattern is judged to be not reverse tapered (NO) if the amount of change ΔW₁ in the white band width of the measurement target pattern is smaller than the threshold T. In this case, the processing goes to step S41.

In step S41, the side wall angle of the measurement target pattern is measured by a different method suitable for the forward tapered pattern.

For instance, the side wall angle may be measured on the basis of a relation between a current value of the electron beam 9 and the white band width as described in Patent Document 2.

Alternatively, the side wall angle of the pattern may be found by: generating differential signals by obtaining differences between signals sent from a plurality of electron detectors 8 (see FIG. 1) arranged in the electron scanning unit 10; finding widths from a lower end to an upper end of a side wall of a pattern on the basis of the differential signals, and then on the basis of the widths from the lower end to the upper end of the side wall of the pattern and a height of the pattern.

As described above, the side wall angle can be measured according to the embodiment even when the forward tapered pattern is included in the measurement target pattern.

### EXPERIMENTAL EXAMPLE

Next, an experimental result of actually measuring a side wall angle based on the pattern measurement method of the above-described embodiment will be explained.

First, two line patterns made of chromium were formed as reference patterns on a photomask substrate made of fused silica. The side wall angles of the line patterns were measured by using the AFM. The side wall angle of one reference pattern A₁ was equal to 110° and the side wall angle of the reference pattern B₁ was equal to 95°.

Next, the SEM images at an acceleration voltage of 1000 V and an acceleration voltage of 2000 V were acquired from each of the reference pattern A₁ and the reference pattern B₁, and the white band widths were found from the SEM images.

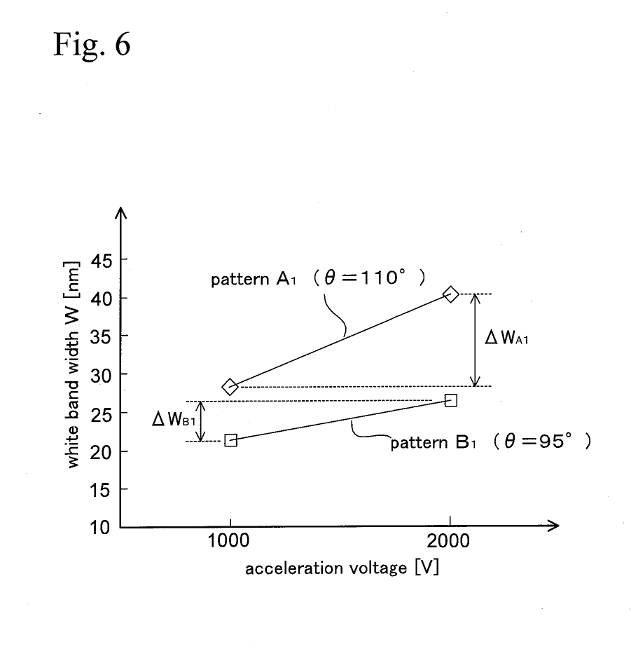

FIG. 6 is a graph showing a result of the measurement of the white band widths regarding the reference patterns in the experimental example, in which the horizontal axis indicates the acceleration voltage and the vertical axis indicates the white band width.

As shown in FIG. 6, the white band width of the pattern A₁ at the acceleration voltage of 1000 V was equal to 28.4 nm and the white band width of the pattern A₁ at the acceleration voltage of 2000 V was equal to 40.3 nm.

From these results, an amount of change ΔW_{A1} in the white band width of the pattern A₁ between the acceleration voltages of 1000 V and 2000 V is obtained as 40.3 nm−28.4 nm=11.9 nm.

In the meantime, the white band width of the pattern B₁ at the acceleration voltage of 1000 V was equal to 21.4 nm and the white band width of the pattern B₁ at the acceleration voltage of 2000 V was equal to 26.5 nm.

From these results, an amount of change ΔW_{B1} in the white band width of the pattern B₁ between the acceleration voltages 1000 V and 2000 V is obtained as 26.5 nm−21.4 nm=5.1 nm.

Next, the reference rate of change α was obtained as described below based on the side wall angles as well as the amounts of change in the white band width of the respective patterns A₁ and B₁, and in accordance with the formula (1):

α=(11.9 nm−5.1 nm)/(110°−95°)=0.45 [nm/degrees].

Then, the threshold T used for judging whether or not a pattern is reverse tapered was obtained.

The threshold T was obtained in accordance with the following calculation by assigning the value 95° of the side wall angle of the pattern B₁ to the parameter θ_{B}, assigning the value 5.1 nm of the amount of change in the white band width of the pattern B₁ to the parameter ΔW_{B}, and assigning the value 0.45 [nm/degrees] to the reference rate of change α, in formula (4):

T=5.1−(95−90)×0.45=2.85 nm.

Next, the measurement target pattern was measured.

First, the SEM images at the acceleration voltage of 1000 V and the acceleration voltage of 2000 V were acquired from the measurement target pattern, and the white band widths of the measurement target pattern were detected from the SEM images.

As a result, the white band width at the acceleration voltage of 1000 V was equal to 26.7 nm and the white band width at the acceleration voltage of 2000 V was equal to 33.7 nm.

Accordingly, the amount of change in the white band width of the measurement target pattern between the acceleration voltages of 1000 V and 2000 V was found to be equal to 7.0 nm.

This amount of change is greater than the value 2.85 nm of the threshold T. Hence, the measurement target pattern turns out to be a reverse tapered pattern.

Next, the side wall angle θ₁ of the measurement target pattern was calculated in accordance with the formula (3):

θ₁=95°+(7.0°−5.1°)/0.45 [nm/°]=99.2°

Thus, the side wall angle of the measurement target pattern was found to be equal to 99.2°.

Meanwhile, the side wall angle of the measurement pattern was measured by using the AFM. The result turned out to be equal to 99°.

Thus, the method of measuring a side wall angle according to the embodiment was confirmed to be able to obtain the result equivalent to the measurement using the AFM.

The pattern measurement method and pattern measurement apparatus described above in the embodiments are capable of promptly performing inspection on a side wall angle of a reverse tapered pattern such as a photomask. Hence, the method and apparatus are suitable for manufacturing process management involving pattern etching conditions and so forth.

Moreover, the method and apparatus are capable of performing non-destructive inspection and therefore avoid the occurrence, of waste products when sampling inspection of the products is conducted.

What is claimed is:

1. A pattern measurement method comprising the steps of:
acquiring scanning electron microscopic images of a measurement target pattern respectively at least two predetermined acceleration voltages;
detecting white band widths of the measurement target pattern from the scanning electron microscopic images;
finding an amount of change in the white band width by obtaining a difference between the detected white band widths; and
finding a side wall angle of the measurement target pattern based on the amount of change in the white band width.

2. The pattern measurement method according to claim 1, wherein the side wall angle of the measurement target pattern is calculated on the basis of a relation between a side wall angle and an amount of change in a white band width obtained in advance by using a reference pattern having a known side wall angle.

3. The pattern measurement method according to claim 2, wherein, in order to obtain the relation between the side wall angle and the amount of change in the white band width in advance, the method further comprises the steps of:
acquiring scanning electron microscopic images of a first reference pattern having a first side wall angle and scanning electron microscopic images of a second reference pattern having a second side wall angle at least two predetermined acceleration voltages;
detecting white band widths of the first reference pattern and the second reference pattern from the scanning electron microscopic images;
calculating an amount of change in the white band width of the first reference pattern and an amount of change in the white band width of the second reference pattern between the different acceleration voltages by obtaining differences in the detected white band widths; and
finding a reference rate of change representing an amount of change in the white band width per unit angle of the side wall angle by dividing a difference between the amount of change in the white band width of the first reference pattern and the amount of change in the white band width of the second reference pattern by a difference between the side wall angle of the first reference pattern and the side wall angle of the second reference pattern.

4. The pattern measurement method according to claim 3, wherein the side wall angle of the measurement target pattern is calculated as
θ₁=θ_{A}+(ΔW₁−ΔW_{A})/α
where θ_{A} is the first side wall angle, ΔW_{A} is the amount of change in the white band width of the first reference pattern, ΔW₁ is the amount of change in the white band width of the measurement target pattern, a is the reference rate of change, and θ₁ is the side wall angle of the measurement target pattern.

5. The pattern measurement method according to claim 2, wherein the measurement target pattern and the reference pattern are made of the same material.

6. The pattern measurement method according to claim 3, wherein the scanning electron microscopic images of the reference patterns are acquired by calculation using a scanning electron microscope simulator.

7. The pattern measurement method according to claim 2, wherein the measurement target pattern and the reference pattern are wide reverse tapered patterns.

8. The pattern measurement method according to claim 1, further comprising the step of:
judging whether or not the measurement target pattern is reverse tapered prior to the step of finding a side wall angle of the measurement target pattern, the judgment being made on the basis of the amount of change in the white band width of the measurement target pattern.

9. A pattern measurement apparatus comprising:
an electron scanning unit configured to scan a measurement target pattern with an electron beam at least two predetermined acceleration voltages;
a signal processing unit configured to acquire a scanning electron microscopic image based on secondary electrons generated by the scanning of the electron beam at the predetermined acceleration voltages respectively; and
a measurement data processing unit configured to find a side wall angle of the measurement target pattern based on the scanning electron microscopic images acquired by the signal processing unit, wherein
the measurement data processing unit
detects white band widths of the measurement target pattern from the scanning electron microscopic images,
finds an amount of change in the white band width by obtaining a difference between the detected white band width, and
finds a side wall angle of the measurement target pattern based on the amount of change in the white band width.
